(19) United States
(12) Patent Application Publication
(10) Pub. No.: US 2011/0165750 A1
(43) Pub. Date: Jul. 7, 2011

(54) METHODS OF MANUFACTURING SEMICONDUCTOR DEVICES INCLUDING STRUCTURES

(75) Inventors: Jun-Kyu Yang, Seoul (KR); Young-Geun Park, Suwon-si (KR); Ki-Hyun Hwang, Seongnam-si (KR); Han-Mei Choi, Seoul (KR); Chan-Jin Park, Yongin-si (KR)

(73) Assignee: Samsung Electronics Co., Ltd.

(21) Appl. No.: 12/984,940

(22) Filed: Jan. 5, 2011

(30) Foreign Application Priority Data
Jan. 5, 2010 (KR) 10-2010-0000287

(51) Int. Cl. H01L 21/336

(52) U.S. Cl. 438/287; 438/197; 438/585; 257/E21.422; 257/E21.409

(57) ABSTRACT

In methods of manufacturing a semiconductor device, a plurality of gate structures spaced apart from each other and oxide layer patterns. A sputtering process using the oxide layer patterns as a sputtering target to connect the oxide layer patterns on the adjacent gate structures to each other is performed, so that a gap is formed between the gate structures. A volume of the gap is formed uniformly to have desired volume by controlling a thickness of the oxide layer patterns.

### CLAIM OF PRIORITY

This application claims priority under 35 USC §119 to Korean Patent Application No. 10-2010-0000287, filed on Jan. 5, 2010 in the Korean Intellectual Property Office (KIPO), the contents of which are herein incorporated by reference in their entirety.

### BACKGROUND

1. Field

Example embodiments according to the inventive concept relate to semiconductor devices, methods of manufacturing a semiconductor device and methods of forming a wiring structure. More particularly, example embodiments according to the inventive concept relate to forming semiconductor devices including oxide bridges defining voids therein, such as wiring structures.

2. Description of the Related Art

Recently, as semiconductor devices have been highly integrated, a threshold voltage changes due to the parasitic capacitance between word lines.

### SUMMARY

According to example embodiments according to the inventive concept, there is provided a method of manufacturing a semiconductor device. In the method, a plurality of gate structures and oxide layer patterns may be formed on a substrate sequentially. The gate structures may be spaced apart from each other. A sputtering process using the oxide layer patterns as a sputtering target to connect the oxide layer patterns on the adjacent gate structures to each other may be performed, so that a gap may be formed between the gate structures.

In the example embodiments according to the inventive concept, during the sputtering process, portions of the oxide layer patterns may be deposited on sidewalls of the gate structures, so that the oxide layer patterns on the adjacent gate structures may be connected to each other.

In the example embodiments according to the inventive concept, during the sputtering process, an oxide thin film may be further formed on the sidewalls of the gate structures and the substrate, and the gap may be defined by the oxide layer patterns and the oxide thin film.

In the example embodiments according to the inventive concept, a volume of the gap may be controlled by a thickness of the oxide layer patterns.

In the example embodiments according to the inventive concept, the sputtering process may be performed using inert gas and at least one of oxygen and hydrogen.

In the example embodiments according to the inventive concept, the sputtering process may be performed using oxygen, hydrogen and argon.

In the example embodiments according to the inventive concept, after forming the gate structures and the oxide layer patterns, a protection layer on the gate structures and the oxide layer patterns may be formed, and the protection layer may reduce the gate structures from being damaged by the sputtering process.

In the example embodiments according to the inventive concept, the protection layer may include silicon nitride or silicon oxide.

In the example embodiments according to the inventive concept, a tunnel insulating layer may be formed on the substrate prior to forming the gate structures and the oxide layer patterns. An impurity region may be formed at upper portions of the substrate adjacent to the gate structures. Each of the gate structures may include a floating gate, a dielectric layer pattern and a first control gate sequentially stacked on the tunnel insulating layer.

In the example embodiments according to the inventive concept, the first control gate may include polysilicon doped with impurities. An ohmic contact may be formed on the first control gate after the sputtering process. A second control gate including a metal may be formed on the ohmic contact.

In the example embodiments according to the inventive concept, an oxide layer covering the oxide layer patterns and the gate structures may be formed on the substrate. An upper portion of the oxide layer may be removed until a top surface of the first control gate is exposed. A metal layer on the first control gate and the oxide layer may be formed. A metal silicide on the first control gate may be formed by performing an annealing process to the metal layer.

In the example embodiments according to the inventive concept, a tunnel insulating layer may be formed on the substrate prior to forming the gate structures and the oxide layer patterns. An impurity region may be formed at upper portions of the substrate adjacent to the gate structures after forming the gate structures and the oxide layer patterns. Each of the gate structures may include a charge trapping layer pattern, a blocking layer and a gate electrode sequentially stacked on the tunnel insulating layer.

In the example embodiments according to the inventive concept, the each of the gate structures may be formed to extend in a first direction, and the gate structures may be formed to be apart from each other in a second direction perpendicular to the first direction.

According to example embodiments according to the inventive concept, there is provided a method of forming a wiring structure. In the method, a plurality of wirings spaced apart from each other and oxides patterns may be formed on the wirings. A sputtering process using the oxide layer patterns as a sputtering target to connect the oxide layer patterns on the adjacent gate structures to each other may be performed, so that a gap may be formed between the gate structures.

In the example embodiments according to the inventive concept, during the sputtering process, portions of the oxide layer patterns may be deposited on sidewalls of the wirings, so that the oxide layer patterns on the adjacent gate structures may be connected to each other.

In the example embodiments according to the inventive concept, during the sputtering process, an oxide thin film may be further formed on the sidewalls of the wirings and the substrate. The gap may be defined by the oxide layer patterns and the oxide thin film.

In the example embodiments according to the inventive concept, a volume of the gap may be controlled by a thickness of the oxide layer patterns.

In the example embodiments according to the inventive concept, a protection layer may be formed on the side walls of the wirings and the oxide layer patterns after forming the wirings and the oxide layer patterns. The protection layer may reduce the wirings from being damaged by the sputtering process.

According to example embodiments according to the inventive concept, there is provided a semiconductor device. A plurality of gate structures may be formed on a tunnel insulating layer on a substrate. The gate structures may include a floating gate, a dielectric layer pattern and a control gate, and the gate structures may be formed to be apart from each other. An impurity region may be formed at upper portions of the substrate adjacent to the gate structures. A first oxide layer structure may be formed between the gate structures and may define a gap with the gate structures and the substrate. A top surface of the gap may be higher than a top surface of the floating gate.

In the example embodiments according to the inventive concept, an oxide thin film may be formed on sidewalls of the gate structures and the substrate. The gap may be defined by the oxide layer patterns and a second oxide layer structure including the oxide thin film.

### BRIEF DESCRIPTION OF THE DRAWINGS

Example embodiments according to the inventive concept will be more clearly understood from the following detailed description taken in conjunction with the accompanying drawings. FIGS. 1 to 24 represent non-limiting, example embodiments according to the inventive concept as described herein.

FIGS. 1 to 10 are cross-sectional views illustrating a method of manufacturing a semiconductor device in accordance with example embodiments according to the inventive concept;

FIGS. 11 to 17 are cross-sectional views illustrating a method of manufacturing a semiconductor device in accordance with other example embodiments according to the inventive concept;

FIGS. 18 to 20 are cross-sectional views illustrating a method of manufacturing a semiconductor device in accordance with still other example embodiments according to the inventive concept;

FIGS. 21 to 24 are cross-sectional views illustrating a method of forming a wiring structure in accordance with example embodiments according to the inventive concept.

### DETAILED DESCRIPTION OF THE EMBODIMENTS ACCORDING TO THE INVENTIVE CONCEPT

Various example embodiments according to the inventive concept will be described more fully hereinafter with reference to the accompanying drawings, in which some example embodiments according to the inventive concept are shown. The present inventive concept may, however, be embodied in many different forms and should not be construed as limited to the example embodiments according to the inventive concept set forth herein. Rather, these example embodiments according to the inventive concept are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments according to the inventive concept only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, however do not preclude the presence or addition of one or more other features, integers, steps, operations, elements, components, and/or groups thereof.

It will be understood that, as used herein, the term “ohmic” refers to where an impedance associated therewith is substantially given by the relationship of Impedance=V/I, where V is a voltage across the item and I is the current, at substantially all expected operating frequencies (i.e., the impedance associated with the ohmic item is substantially the same at all operating frequencies). For example, in some embodiments according to the inventive concept, an ohmic contact can be a contact with a specific contact resistivity of less than about 10 e-03 ohm-cm2 and, in some embodiments less than about 10 e-04 ohm-cm 2. Thus, a contact that is rectifying or that has a high specific contact resistivity, for example, a specific contact resistivity of greater than about 10 e-03 ohm-cm2, is not an ohmic contact as that term is used herein.

Example embodiments according to the inventive concept are described herein with reference to cross-sectional illustrations that are schematic illustrations of idealized example embodiments according to the inventive concept (and intermediate structures). As such, variations from the shapes of the illustrations as a result, for example, of manufacturing techniques and/or tolerances, are to be expected. Thus, example embodiments according to the inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIGS. 1 to 10 are cross-sectional views illustrating a method of manufacturing a semiconductor device in accordance with example embodiments according to the inventive concept.

Referring to FIG. 1, a tunnel insulating layer 110, a floating gate layer 120, a dielectric layer 130, a first control gate layer 140 and a first oxide layer 150 may be stacked on the substrate 100 sequentially.

The substrate 100 may include a semiconductor substrate such as a silicon substrate, a germanium substrate, a silicon-germanium substrate, a silicon-on-insulator (SOI) substrate, a germanium-on-insulator (GOI) substrate, etc. The substrate 100 may further include well regions (not shown) having P-type or N-type impurities.

The tunnel insulating layer 110 may be formed using an oxide such as silicon oxide, an oxynitride such as silicon oxynitride, silicon oxide doped with impurities, a low-k material, etc.

The floating gate layer 120 may be formed using polysilicon doped with impurities or a metal having a high work function such as tungsten, titanium, cobalt, nickel, etc.

The dielectric layer 130 may be formed using an oxide and a nitride to have an ONO structure including an oxide layer/a nitride layer/an oxide layer sequentially stacked on the floating gate layer 120. Alternatively, the dielectric layer 130 may be formed using a metal oxide having a high dielectric constant, thereby having an increased capacitance and improved leakage current characteristics. Examples of the high dielectric metal oxide may include hafnium oxide, titanium oxide, tantalum oxide, zirconium oxide, aluminum oxide, etc.

The first control gate layer 140 may be formed using doped polysilicon, a metal, a metal nitride, a metal silicide, etc. In an example embodiment, the first control gate layer 140 may be formed to have a stacked structure including a doped polysilicon layer, an ohmic layer, a diffusion barrier layer, an amorphous layer and a metal layer sequentially stacked on the dielectric layer 130. For example, the ohmic layer may be formed using titanium (Ti), tantalum (Ta), tungsten (W), molybdenum (Mo), or alloys thereof, and the diffusion barrier may be formed using tungsten nitride, titanium nitride, tantalum nitride, molybdenum nitride, etc., and the amorphous layer may be formed using a refractory metal silicide such as amorphous tungsten silicide (WSiₓ), amorphous titanium silicide (TiSiₓ), amorphous molybdenum silicide (MoSiₓ) or amorphous tantalum silicide (TaSiₓ), and the metal layer may be formed using tungsten, titanium, tantalum, molybdenum or alloys thereof.

The first oxide layer 150 may be formed using an oxide such as silicon oxide and high density plasma (HDP) oxide, etc.

Alternatively, a charge trapping layer 120, a blocking layer 130, a gate electrode layer 140 and the first oxide layer 150 may be formed on the tunnel insulating layer 110 sequentially.

The charge trapping layer 120 may be formed using a nitride such as silicon nitride or a hafnium oxide such as hafnium silicon oxide. The blocking layer 130 may be formed using silicon oxide or a high dielectric metal oxide such as hafnium oxide, titanium oxide, tantalum oxide, zirconium oxide, aluminum oxide, etc. The gate electrode layer 140 may be formed using doped polysilicon, a metal, a metal nitride, a metal silicide, etc.

Hereinafter, the structure including the tunnel insulating layer 110, the floating gate layer 120, the dielectric layer 130, the first control gate layer 140 and the first oxide layer 150 sequentially stacked on the substrate 100 will be described.

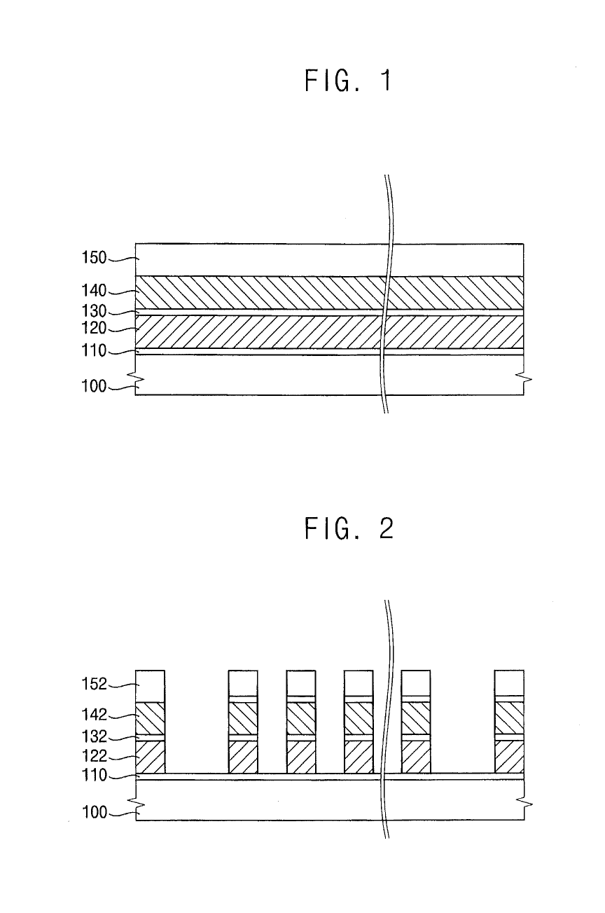

Referring to FIG. 2, the first oxide layer 150, the first control gate layer 140, the dielectric layer 130 and the floating gate layer 120 may be etched by a photolithography process so that a first oxide layer pattern 152 and a plurality of gate structures including a floating gate 122, a dielectric layer pattern 132 and a first control gate 142 sequentially stacked on the tunnel insulating layer 110 may be formed. In this case, the tunnel insulating layer 110 may be also patterned, and each gate structure may include a tunnel insulating layer pattern. Each gate structure may be formed to extend in a first direction, and the gate structures may be formed to be apart from each other in a second direction perpendicular to the first direction.

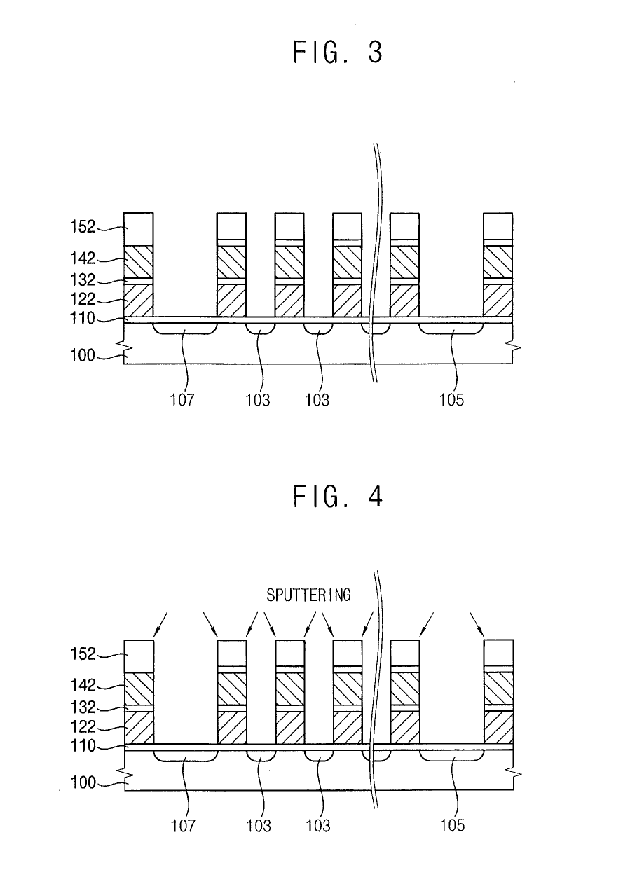

Referring to FIG. 3, an ion implantation process may be performed using the gate structures and the first oxide layer patterns 152 as an ion implantation mask so that impurity regions 103, 105, 107 may be formed at upper portions of the substrate 100 adjacent to the gate structures. The first impurity region 103 may have a relatively narrow width, and the second and the third impurity regions 105 and 107 may have a relatively wide width.

Referring to FIG. 4, a sputtering process may be performed using each of the first oxide layer patterns 152 as a sputtering target.

Particularly, after generating plasma by providing inert gas such as argon, helium, etc. at a certain power, the generated plasma may be applied to upper portions, particularly, upper edge portions of the first oxide layer patterns 152 so that oxygen may be separated from the first oxide layer patterns 152. When the first oxide layer patterns 152 include silicon oxide, silicon may be also separated from the first oxide layer patterns 152.

In addition to the inert gas, oxygen gas or hydrogen gas may be further provided. In an example embodiment, argon gas, oxygen gas and hydrogen gas may be provided at a flow rate ratio of about 36:3:1. In an example embodiment, the sputtering process may be performed at a temperature of about 400 to about 600° C. under a pressure of about 50 Torr to about 150 Torr and with a power of about 500 W to about 600 W.

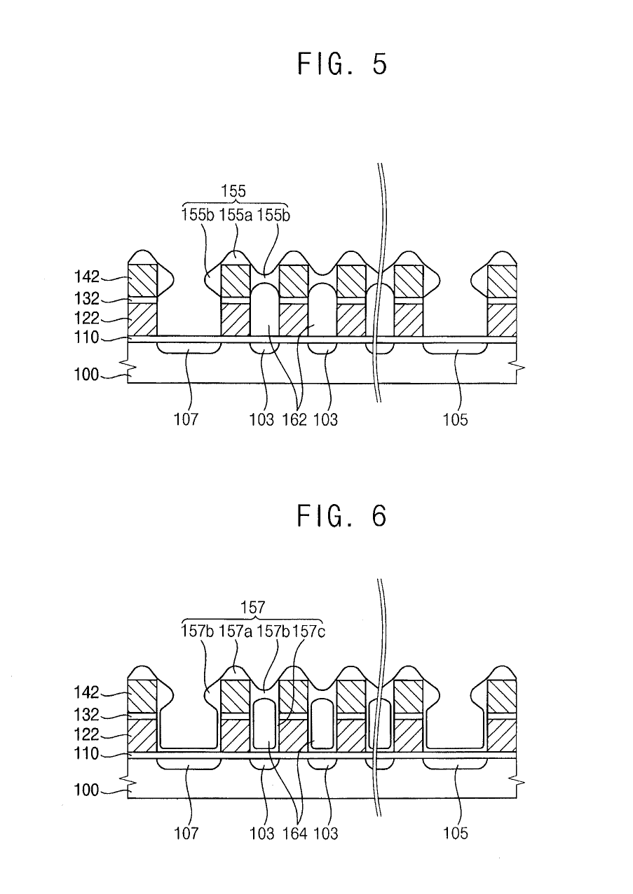

Referring to FIG. 5, by the sputtering process, portions of the first oxide layer patterns 152 may be removed and deposited on sidewalls of the gate structures, and thus the first oxide layer patterns 152 may be connected to each other to form a first oxide layer structure 155.

The first oxide layer structure 155 may include an upper portion 155a on a top surface of each gate structure and a lateral portion 155b on a sidewall of each gate structure. The lateral portion 155b of the first oxide layer structure 155, the sidewalls of the gate structures and the tunnel insulating layer 110 may form a first gap (or void) 162 by promoting the formation of an oxide bridge between the plurality of gate structures. If each gate structure includes the tunnel insulating layer pattern, the lateral portion 155b, the sidewalls of the gate structures and the substrate 100 may define the first gap (or void) 162 beneath the oxide bridge and above the substrate 100. The first gap 162 (or void) is devoid of the gate structures (such as the materials used to form the structures, but may include incidental remnants from the sputtering process).

The volume of the first gap 162 may depend on the height of the lateral portion 155b of the first oxide layer structure 155, and the height of the lateral portion 155b may depend on the thickness of the first oxide layer pattern 152. Thus, the volume of the first gap 162 may be changed by controlling the thickness of the first oxide layer pattern 152, and forming the first gap 162 having a desired size may be more readily promoted. In example embodiments according to the inventive concept, a top surface of the first gap 162 may be formed to be higher than that of the floating gate 122.

As shown in FIG. 6, during the sputtering process, a first oxide thin film 157c may be further formed on the sidewalls of the gate structures and the tunnel insulating layer 110 or the substrate 100.

Particularly, during the sputtering process, oxygen separated from the first oxide layer patterns 152 may be thinly deposited on the sidewalls of the gate structures and the tunnel insulating layer 110 or the substrate 100 so that the first oxide thin film 157c may be formed. If the sputtering process is performed using oxygen gas, the first oxide thin film 157c may be formed on the sidewalls of the gate structures and the tunnel insulating layer 110 or the substrate 100 by plasma oxidation. A total oxide layer shown in FIG. 6 may be called a second oxide layer structure 157. The second oxide layer structure 157 may include an upper portion 157a, a lateral portion 157b and the first oxide thin film 157c. Additionally, the lateral portion 157b of the second oxide layer structure 157, the sidewalls of the gate structures and the tunnel insulating layer 110 or the substrate 100 may define a second gap 164.

The first oxide thin film 157c may be formed by a sputtering process or a plasma oxidation process, and thus may be thinner and more uniform than an oxide layer formed by a chemical vapor deposition (CVD) process. When the first oxide thin film 157c is formed on the tunnel insulating layer 110 including an oxide, the thickness of the first oxide thin film 157c may be very thin.

When the first oxide thin film 157c is formed by a plasma oxidation process using oxygen gas, a plasma oxidation having strong anisotropic characteristics may be performed to reduce the denaturation and damage of the sidewalls of the gate structures.

Hereinafter, a method of manufacturing the semiconductor device having the second oxide layer structure 157 will be described.

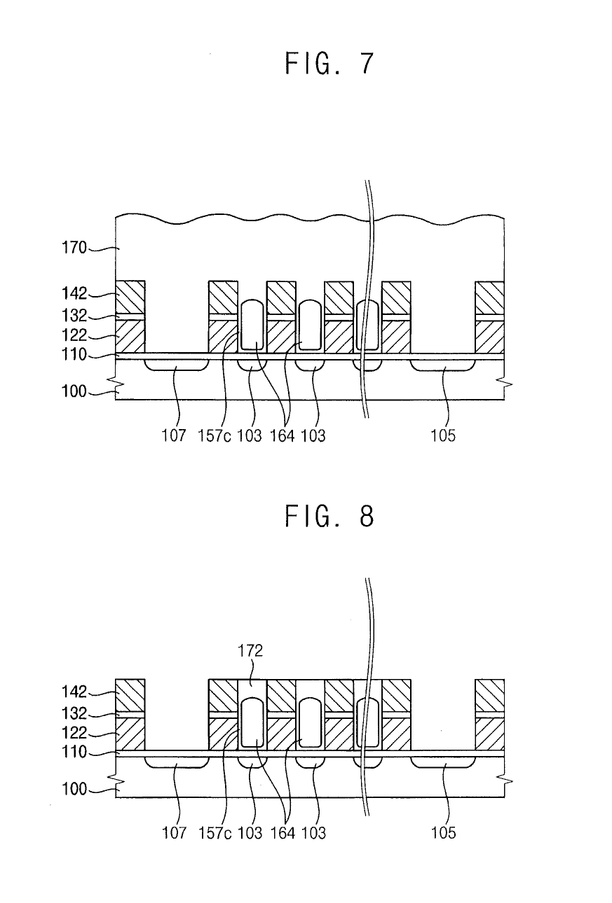

Referring to FIG. 7, a second oxide layer 170 covering the second oxide layer structure 157 may be formed on the substrate 100. In example embodiments according to the inventive concept, the second oxide layer 170 may be formed using a material substantially the same as that of the first oxide layer 150. Therefore, the upper portion 157a, the lateral portion 157b and a portion of the first oxide thin film 157c of the second oxide layer structure 157 may be merged with the second oxide layer 170.

Referring to FIG. 8, an upper portion of the second oxide layer 170 may be removed by performing a chemical mechanical polishing (CMP) process and/or an etch back process until a top surface of the gate structures is exposed, and portions of the second oxide layer 170 on the second and third impurity regions 105 and 107 may be removed by a photolithography process. Therefore, second oxide layer patterns 172 may be formed between the gate structures.

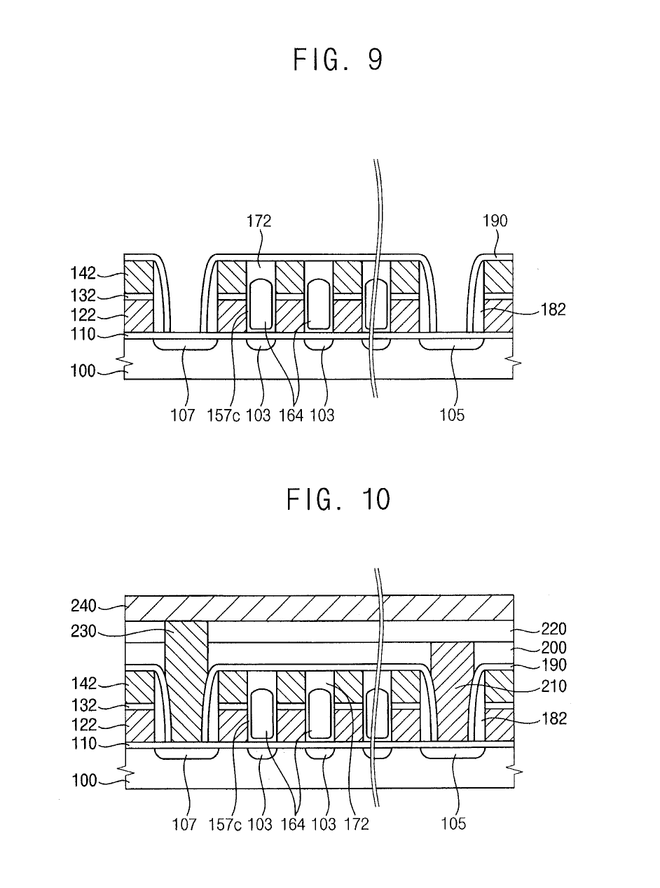

Referring to FIG. 9, a spacer layer may be formed on the gate structures, the second oxide layer patterns 172 and the tunnel insulating layer 110, and the spacer layer may be partially etched by an anisotropic etching process to form a spacer 182 on parts of the sidewalls of the gate structures on which the second oxide layer patterns 172 are not formed. The spacer layer may be formed using a nitride such as silicon nitride or an oxide such as silicon oxide.

A capping layer 190 covering the gate structures, the second oxide layer patterns 172 and the spacer 182 may be formed. The capping layer 190 may be formed using a nitride or an oxide.

Referring to FIG. 10, a first insulating interlayer 200 may be formed on the tunnel insulating layer 110 and the capping layer 190 so that spaces between capping layers 190 may be sufficiently filled. The first insulating interlayer 200 may be formed using an oxide such as boron phosphorus silicate glass (BPSG), undoped silicate glass (USG), silicon on glass (SOG), etc.

A common source line (CSL) 210 may be formed on the second impurity region 105 through the first insulating interlayer 200. The CSL 210 may be formed using doped polysilicon, a metal or a metal silicide.

A second insulating interlayer 220 may be formed on the first insulating interlayer 200 and the common source line 210. The second insulating interlayer 220 may be formed using an oxide such as BPSG USG, SOG, etc.

A bit line contact 230 may be formed on the second impurity region 107 through the first and second insulating interlayers 200 and 220. The bit line contact 230 may be formed using a metal, doped polysilicon, etc.

A bit line 240 may be formed on the second insulating interlayer 220 to contact the bit line contact 230. The bit line 240 may be formed to extend in the first direction. The bit line may be formed using a metal, doped polysilicon, etc.

By performing the above processes, the semiconductor device in accordance with example embodiments according to the inventive concept may be formed. In FIGS. 1 to 10, a method of manufacturing a NAND flash memory device is illustrated. However, the present inventive concept may be applied to a method of manufacturing a NOR flash memory device or other semiconductor devices.

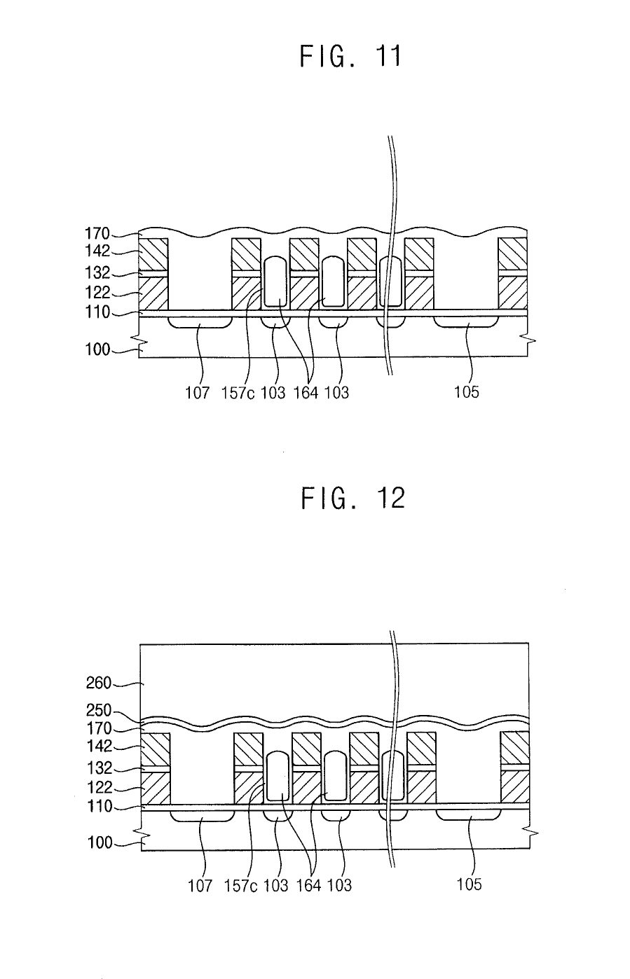

FIGS. 11 to 17 are cross-sectional views illustrating a method of manufacturing a semiconductor device in accordance with other example embodiments according to the inventive concept. The method of manufacturing the semiconductor device is substantially the same as or similar to that illustrated with reference to FIGS. 1 to 7, except that the first control gate layer 140 is formed using doped polysilicon. Therefore, like elements refer to like reference numerals and detail explanations thereon are omitted herein.

Referring to FIG. 11, the upper portion of the second oxide layer 170 shown in FIG. 7 may be removed by an etch back process. In example embodiments according to the inventive concept, the second oxide layer 170 may be removed until the second oxide layer 170 has a height similar to that of the top surface of the gate structures.

Referring to FIG. 12, an etch stop layer 250 may be formed on the second oxide layer 170. The etch stop layer 250 may be formed using a material having an etching selectivity with respect to an insulating layer 260 subsequently formed. For example, the etch stop layer 250 may be formed using a nitride such as silicon nitride.

The insulating layer 260 may be formed on the etch stop layer 250. The insulating layer 260 may be formed using an oxide such as high density plasma (HDP) oxide.

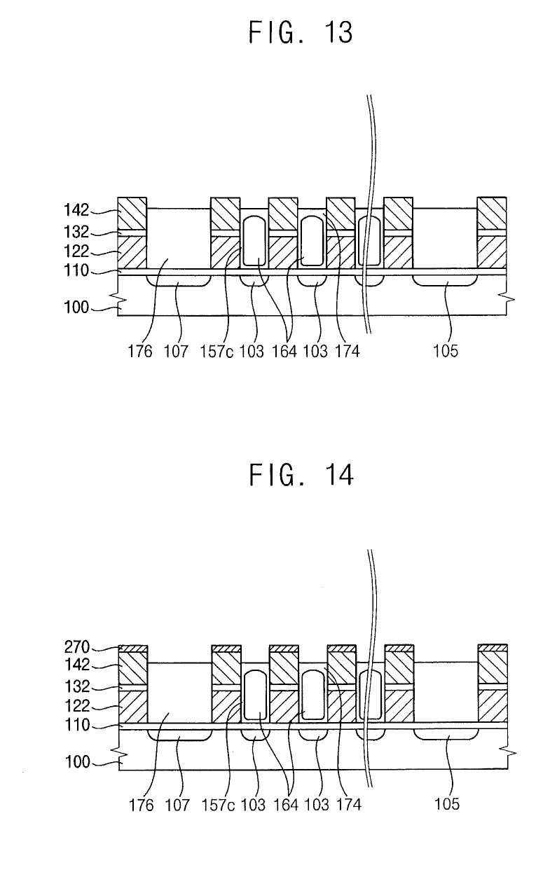

Referring to FIG. 13, after removing the insulating layer 260 by a CMP process until the etch stop layer 250 is exposed, the etch stop layer 250 and a portion of the second oxide layer 170 may be removed by an etch back process. By the CMP process and the etch back process, the top surface of the gate structures may be exposed, and the second oxide layer 170 may be changed to a third oxide layer pattern 174 and a fourth oxide layer pattern 176. The third oxide layer pattern 174 may be formed on the first impurity region 103, and the fourth oxide layer pattern 176 may be formed on the second and third impurity regions 105 and 107.

Referring to FIG. 14, a first metal layer may be formed on the gate structures, the third and fourth oxide layer patterns 174 and 176, and an annealing process may be performed. The first metal layer may be formed using cobalt, tungsten, etc. Therefore, an ohmic contact 270 having a metal silicide such as cobalt silicide or tungsten silicide may be formed on each of the first control gates 142 having doped polysilicon. After forming the ohmic contacts 270, the first metal layer formed on the third and fourth oxide layer patterns 174 and 176 may be removed.

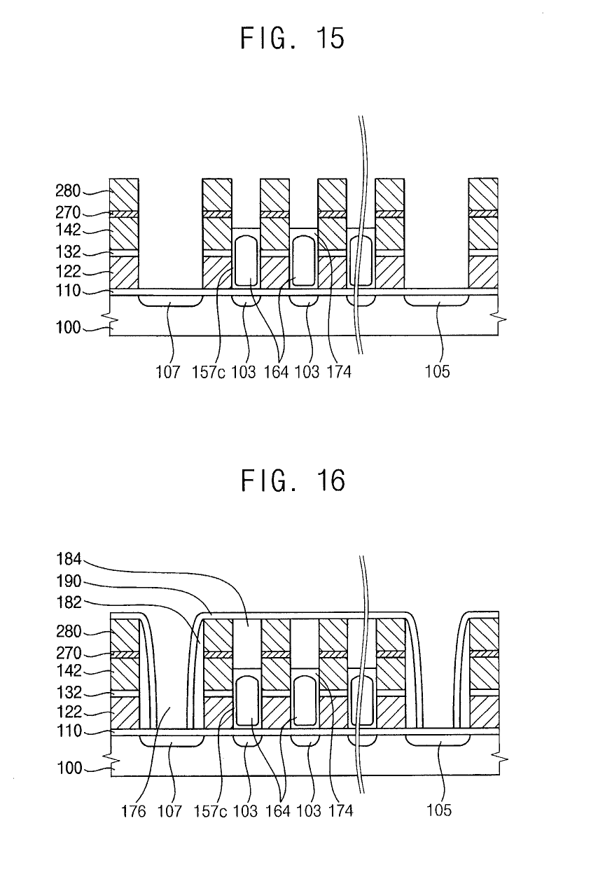

Referring to FIG. 15, a second metal layer may be formed on the ohmic contacts 270, the third and fourth oxide layer patterns 174 and 176. The second metal layer may be formed using tungsten, titanium, tantalum, molybdenum or alloys thereof. Portions of the second metal layer on the third and fourth oxide layer patterns 174 and 176 may be removed so that a second control gate 280 may be formed on the ohmic contacts 270. Therefore, a control gate structure having the first control gate 142 including doped polysilicon, the ohmic contact 270 including a metal silicide and the second control gate 280 including a metal may be formed. The control gate structure, the floating gate 122 and the dielectric layer pattern 132 may define a gate structure. The fourth oxide layer pattern 176 may be removed.

Referring to FIG. 16, a filler 184 may be formed on the third oxide layer pattern 174 to fill spaces between the gate structures. A spacer layer may be formed on the gate structures, the filler 184 and the tunnel insulating layer 110, and the spacer layer may be partially etched by an anisotropic etching process to form a spacer 182 on parts of the sidewalls of the gate structures on which the third oxide layer patterns 174 or the filler 184 is not formed. The spacer layer may be formed using a nitride such as silicon nitride or an oxide such as silicon oxide. A capping layer 190 covering the gate structures, the spacer 182 and the pillar 184 may be further formed. The capping layer 190 may be formed using a nitride or an oxide.

Referring to FIG. 17, the semiconductor device may be formed by performing processes substantially the same as or similar to those illustrated with reference to FIG. 10.

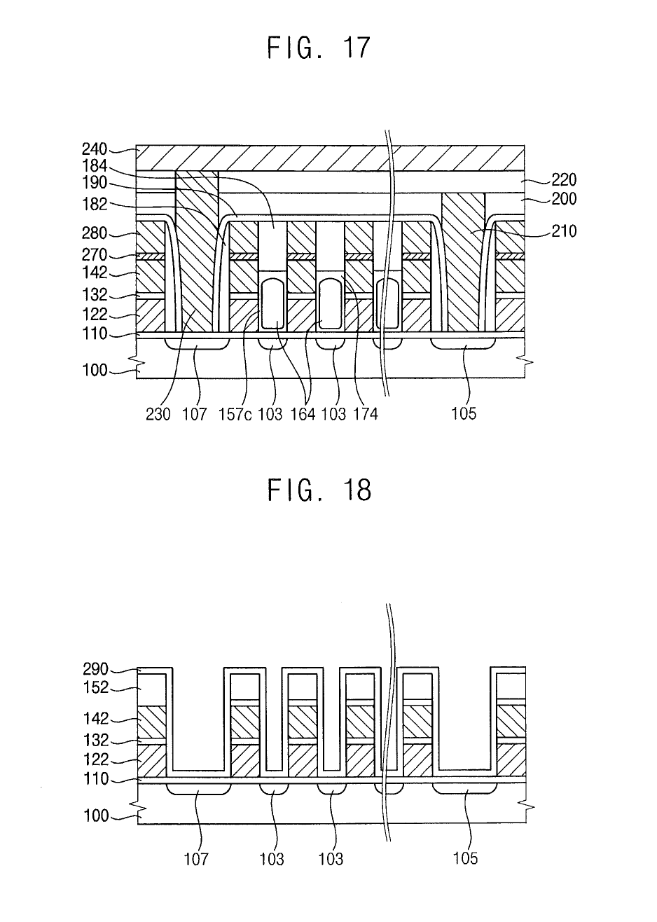

FIGS. 18 to 20 are cross-sectional views illustrating a method of manufacturing a semiconductor device in accordance with still other example embodiments according to the inventive concept. The method of manufacturing the semiconductor device is substantially the same as or similar to that illustrated with reference to FIGS. 1 to 10, except that a protection layer is further formed prior to a sputtering process. Therefore, like elements refer to like reference numerals and detail explanations thereon are omitted herein.

Referring to FIG. 18, after performing the processes illustrated with reference to FIGS. 1 to 3, a protection layer 290 covering the gate structures may be formed on the substrate 100. The protection layer 290 may reduce or prevent the sidewalls of the gate structures from being damaged or denatured in a sputtering process subsequently performed. The protection layer 290 may be formed using silicon oxide or silicon nitride.

In an example embodiment, the protection layer 290 may be formed on the gate structures, the first oxide layer patterns 152 and the tunnel insulating layer 110.

In another example embodiment, the protection layer 290 may be formed on the gate structures and the first oxide layer patterns 152.

In still another example embodiment, the protection layer 290 may be formed only on the sidewalls of the gate structures. In this case, unlike the processes illustrated with reference to FIGS. 1 to 3, after forming the gate structures on the substrate 100, the protection layer 290 covering the gate structures may be formed and a portion of the protection layer 290 may be etched so that the protection layer 290 may be formed on the sidewalls of the gate structures. Then, the first oxide layer patterns 152 may be formed on the gate structures so that the protection layer 290 covering only the sidewalls of the gate structures may be formed.

Hereinafter, a method of manufacturing the semiconductor device having the protection layer 290 on the gate structures, the first oxide layer patterns 152 and the tunnel insulating layer 110 will be described.

Referring to FIG. 19, a second oxide layer structure 157 may be formed by performing processes substantially the same as or similar to those illustrated with reference to FIGS. 4 to 6. However, the sputtering process may be performed after the protection layer 290 has been formed on the gate structures and the tunnel insulating layer 110. Therefore, when the protection layer 290 includes a material different from that of the first oxide layer patterns 152, the second oxide layer structure 157 may include a material different from that shown in FIGS. 4 to 6. Particularly, when the protection layer 290 may includes silicon nitride, a second oxide thin film 157d including nitrogen may be formed on the sidewalls of the gate structures and the tunnel insulating layer 110.

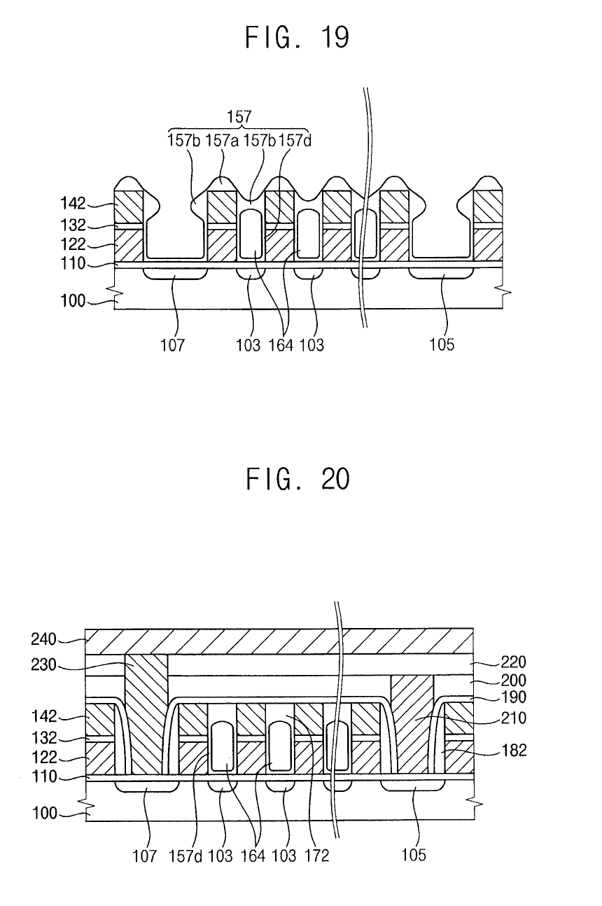

Referring to FIG. 20, the semiconductor device may be formed by performing the processes illustrated with reference to FIGS. 7 to 10.

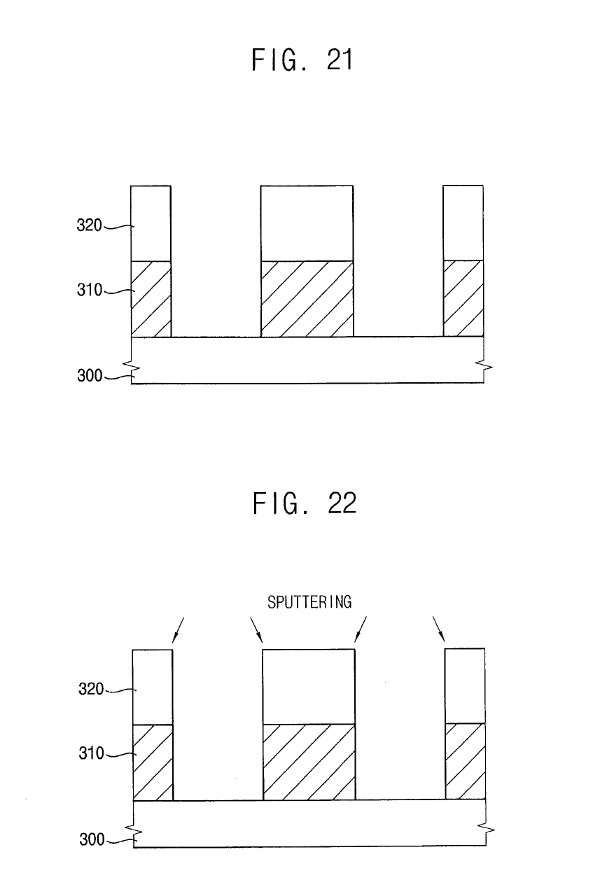

FIGS. 21 to 24 are cross-sectional views illustrating a method of forming a wiring structure in accordance with example embodiments according to the inventive concept.

Referring to FIG. 21, a plurality of wirings 310 spaced apart from each other may be formed on the substrate 300. Various semiconductor devices (not shown) may be formed on the substrate 300. The wirings 310 may be formed using a metal, a metal nitride and doped polysilicon, etc.

A first oxide layer pattern 320 may be formed on the wirings 310. The first oxide layer pattern 320 may be formed using silicon oxide, HDP oxide, etc.

Referring to FIG. 22, a sputtering process may be performed using each of the first oxide layer patterns 320 as a sputtering target. Particularly, after generating plasma by providing inert gas such as argon, helium, etc. at a certain power, the generated plasma may be applied to upper portions, particularly, upper edge portions of the first oxide layer patterns 320 so that oxygen may be separated from the first oxide layer patterns 320. When the first oxide layer patterns 320 include silicon oxide, silicon may be also separated from the first oxide layer patterns 320. In this case, oxygen gas or hydrogen gas may be provided in addition to the inert gas.

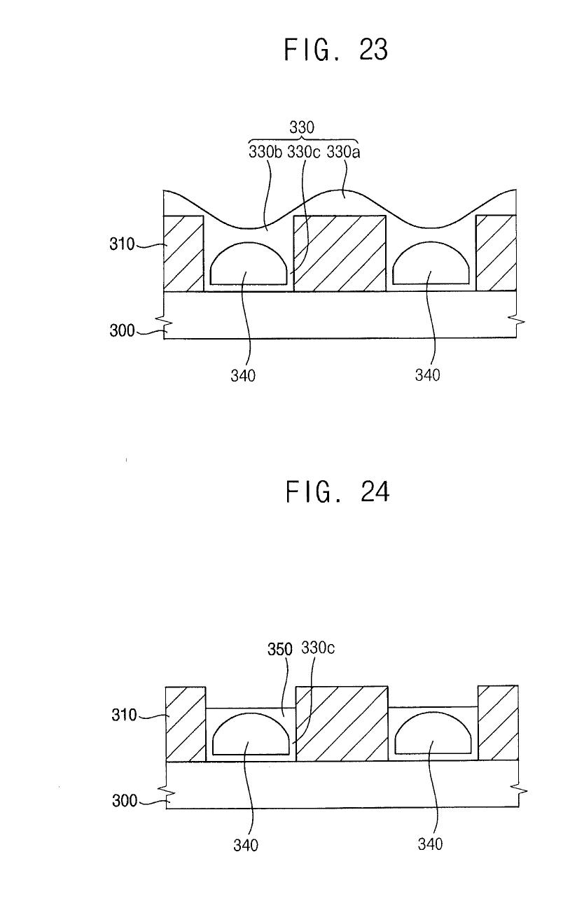

Referring to FIG. 23, by the sputtering process, portions of the first oxide layer patterns 320 may be removed and deposited on sidewalls of the wirings 310, and thus the first oxide layer patterns 320 may be connected to each other and an oxide layer structure 330 may be formed by promoting the formation of an oxide bridge between the wiring structures. The oxide layer structure 330 may include an upper portion 330a on a top surface of the wirings 310 and a lateral portion 330b on the sidewalls of the wirings 310. An oxide thin film 330c may be further formed on the sidewalls of the wirings 310 and the substrate 300. The lateral portion 330b of the oxide layer structure 330 and the oxide thin film 330c may form a gap (or void) 340 beneath the oxide bridge and above the substrate 100. The first gap 162 (or void) is devoid of the wiring structures (such as the materials used to form the structures, but may include incidental remnants from the sputtering process).

Referring to FIG. 24, a second oxide layer pattern 350 may be formed by partially removing the upper portion 330a and the lateral portion 330b of the oxide layer structure 330. In this case, after forming an additional oxide layer (not shown) on the oxide layer structure 330, a CMP process and/or an etch back process may be performed to the oxide layer so that the second oxide layer pattern 350 may be formed. Therefore, the wiring structure having the gap 340 and the wirings 310 may be formed.

As described above, in accordance with example embodiments according to the inventive concept, oxide layer patterns may be formed on gate structures spaced apart from each other, and the oxide layer patterns may be connected to each other by a sputtering process and/or a plasma oxidation process so that a gap may be formed between the gate structures. The volume of the gap may be controlled by controlling the thickness of the oxide layer patterns, and the gap may be formed uniformly. Therefore, semiconductor devices having a reduced parasitic capacitance between the gate structures may be formed easily, and the methods of manufacturing the semiconductor devices may be applied to methods of forming wiring structures.

Foregoing is illustrative of example embodiments according to the inventive concept and is not to be construed as limiting thereof. Although a few example embodiments according to the inventive concept according to the inventive concept have been described, those skilled in the art will readily appreciate that many modifications are possible in the example embodiments according to the inventive concept according to the inventive concept without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments according to the inventive concept according to the inventive concept and is not to be construed as limited to the specific example embodiments according to the inventive concept according to the inventive concept disclosed, and that modifications to the disclosed example embodiments according to the inventive concept according to the inventive concept, as well as other example embodiments according to the inventive concept according to the inventive concept, are intended to be included within the scope of the appended claims.

1. A method of forming a semiconductor device comprising:
forming a plurality of structures separated by a gap on a substrate;
forming an exposed upper layer including an oxide on the plurality of structures; and
sputtering the exposed upper layer to promote growth of a bridge across the gap to connect the structures and to leave a void beneath the bridge between the structures.

2. The method according to claim 1 wherein the void is devoid of the structures and includes remnants of the sputtering including oxygen or hydrogen.

3. The method according to claim 1 wherein the sputtering is configured to particularly target upper outside edges of the exposed upper layer.

4. The method according to claim 1 further comprising:
forming source/drain regions between the structures in the substrate beneath where the void is formed by the sputtering.

5. (canceled)

6. (canceled)

7. (canceled)

8. A method of manufacturing a semiconductor device comprising:
forming a plurality of gate structures and oxide layer patterns on a substrate, the gate structures being spaced apart from each other; and
performing a sputtering process using the oxide layer patterns as a sputtering target to connect the oxide layer patterns on the adjacent gate structures to each other, thereby forming a gap between the gate structures.

9. The method of claim 8, wherein, during the sputtering process, portions of the oxide layer patterns are deposited on sidewalls of the gate structures, so that the oxide layer patterns on the adjacent gate structures are connected to each other.

10. The method of claim 9, wherein, during the sputtering process, an oxide thin film is further formed on the sidewalls of the gate structures and the substrate,
and wherein the gap is defined by the oxide layer patterns and the oxide thin film.

11. The method of claim 8, wherein a volume of the gap is controlled by a thickness of the oxide layer patterns.

12. The method of claim 8, wherein the sputtering process is performed using inert gas and at least one of oxygen and hydrogen.

13. The method of claim 12, wherein the sputtering process is performed using oxygen, hydrogen and argon.

14. The method of claim 8, after forming the gate structures and the oxide layer patterns, further comprising:
forming a protection layer on the gate structures and the oxide layer patterns, the protection layer reducing the gate structures from being damaged by the sputtering process.

15. The method of claim 14, the protection layer includes silicon nitride or silicon oxide.

16. The method of claim 8, further comprising:
forming a tunnel insulating layer on the substrate prior to forming the gate structures and the oxide layer patterns; and
forming an impurity region at upper portions of the substrate adjacent to the gate structures,
wherein each of the gate structures includes a floating gate, a dielectric layer pattern and a first control gate sequentially stacked on the tunnel insulating layer.

17. The method of claim 16, the first control gate includes polysilicon doped with impurities, further comprising:
forming an ohmic contact on the first control gate after the sputtering process; and
forming a second control gate including a metal on the ohmic contact.

18. The method of claim 17, wherein forming the ohmic contact includes:
forming an oxide layer covering the oxide layer patterns and the gate structures on the substrate;
removing an upper portion of the oxide layer until a top surface of the first control gate is exposed;
forming a metal layer on the first control gate and the oxide layer; and
forming a metal silicide on the first control gate by performing an annealing process to the metal layer.

19. The method of claim 8, further comprising:
forming a tunnel insulating layer on the substrate prior to forming the gate structures and the oxide layer patterns; and
forming an impurity region at upper portions of the substrate adjacent to the gate structures after forming the gate structures and the oxide layer patterns,
wherein each of the gate structures includes a charge trapping layer pattern, a blocking layer and a gate electrode sequentially stacked on the tunnel insulating layer.

20. The method of claim 8, the each of the gate structures is formed to extend in a first direction, and the gate structures are formed to be apart from each other in a second direction perpendicular to the first direction.

21. A method of forming a wiring structure comprising:
forming a plurality of wirings spaced apart from each other and oxides patterns on the wirings; and
performing a sputtering process using the oxide layer patterns as a sputtering target to connect the oxide layer patterns on the adjacent gate structures to each other, thereby forming a gap between the gate structures.

22. The method of claim 21, wherein, during the sputtering process, portions of the oxide layer patterns are deposited on sidewalls of the wirings, so that the oxide layer patterns on the adjacent gate structures are connected to each other.

23. The method of claim 22, wherein, during the sputtering process, an oxide thin film is further formed on the sidewalls of the wirings and the substrate,
and wherein the gap is defined by the oxide layer patterns and the oxide thin film.

24. The method of claim 21, wherein a volume of the gap is controlled by a thickness of the oxide layer patterns.

25. The method of claim 21, after forming the wirings and the oxide layer patterns, further comprising:
forming a protection layer on the side walls of the wirings and the oxide layer patterns, the protection layer reducing the wirings from being damaged by the sputtering process.

26. (canceled)

27. (canceled)
